(19) United States
(12) Patent Application Publication
(10) Pub. No.: US 2007/0084497 A1
(43) Pub. Date: Apr. 19, 2007

(54) Solid state direct heat to cooling converter

(76) Inventor: Richard Strnad, Plano, TX (US)

Correspondence Address: Wilson Daniel Swayze, Jr, 3804 Clearwater Ct., Plano, TX, 75025, US

(21) Appl. No.: 11/253,975

(22) Filed: Oct. 19, 2005

(51) Int. Cl. H01L 35/28

(52) U.S. Cl. 136/203

(57) ABSTRACT

A combination of Peltier and Seebeck effect provides effective way to convert thermal energy to cooling. The common electrodes are electrically in contact with both devices cells, the cell generating electricity and the cell converting electricity to cooling. Additional factors providing for superior performance are the diced Peltier elements, and possibility of utilizing different material thermoelectric elements to generate electricity. Relatively low operating temperature of Bismuth Telluride may be increased by selecting materials such as CuAgSe, Si—Ge, BiSbTe and other. These materials may operate at temperatures of 1,000° C. or higher. That may prove advantageous in automobile application where the temperature of exhaust pipe gases is high.

### BACKGROUND OF THE INVENTION

1. Field of the Invention

The present invention relates to thermoelectric energy conversion. It incorporates the inter-conversion of heat and electrical energy for power generation and heat pumping and is based on the Seebeck and Peltier effect.

2. Background of the Invention

The thermoelectric effects in a thermoelectric circuit produce useful heating, cooling and power generation. The efficient operation of devices based upon these effects requires the optimization of circuit parameters, properties of the materials used and the geometries. Since the efficiency of a thermoelectric generator and the coefficient of performance of a thermoelectric heat pump are independent of the capacity of both units, these parameters can be derived on the basis of a single junction.

In FIG. 1, a temperature difference T_{H}−T_{C} is established across the thermoelectric elements and causes a current I to flow through the pair of thermoelectric elements and across the load resistor. This pair of thermoelectric elements, namely the p & n elements shown in FIG. 1 provides the direct conversion of heat to electrical energy with a conversion efficiency, η, which is defined as

$$η = \frac{power supplied to load ( {P}_{O} )}{heat absorbed at hot junction ( {Q}_{H} )} \qquad ( 1 )$$

The emf produced by this thermocouple is
emf=(αₚ−αₙ)(T_{H}−T_{C}) (2)
and this yields useful power across the load

$$\begin{matrix}{P}_{O} = {I}^{2} {R}_{0} & ( 3 ) \\ {P}_{O} = {[ \frac{( {α}_{p} - {α}_{n} ) ( {T}_{1} - {T}_{2} )}{( {R}_{t} + {R}_{O} )} ]}^{2} {R}_{O} & ( 4 ) \\ {R}_{t} = {ρ}_{n} {R}_{t} = {ρ}_{n} \text{/} {γ}_{n} + {ρ}_{p} \text{/} {γ}_{p} & ( 5 )\end{matrix}$$

The heat Q_{H} absorbed at T_{H} (FIG. 1) consists of the Peltier heat Q_{P} and the heat withdrawn from the hot junction Qₕ:

$$\begin{matrix}{Q}_{H} = {Q}_{P} + {Q}_{h} & ( 6 ) \\ {Q}_{P} = {π}_{np} I = {α}_{np} I {T}_{H} & ( 7 ) \\ {V}_{O C} = αΔ T & ( 8 ) \\ I = \frac{{V}_{O C}}{{R}_{t}} & ( 9 ) \\ {α}_{np} = \vert {α}_{n} \vert + \vert {α}_{p} \vert & ( 10 ) \\ I = \frac{{α}_{np} ( {T}_{H} - {T}_{C} )}{{R}_{t} + {R}_{O}} & ( 11 ) \\ {Q}_{h} = {κ}_{t} ( {T}_{H} - {T}_{C} ) - 1 \text{/} 2 {I}^{2} {R}_{t} & ( 12 ) \\ from ( 3 ) {Q}_{H} = {α}_{np} {IT}_{H} + {κ}_{t} ( {T}_{H} - {T}_{C} ) - 1 \text{/} 2 {I}^{2} {R}_{t} & ( 13 ) \\ from ( 1 ) η = \frac{{I}^{2} {R}_{O}}{{α}_{np} {IT}_{H} + {κ}_{t} ( {T}_{H} - {T}_{C} ) - 1 \text{/} 2 {I}^{2} {R}_{t}} & ( 14 )\end{matrix}$$

and the maximum efficiency is

$$\begin{matrix}{η}_{max} = [ \frac{{T}_{H} - {T}_{C}}{{T}_{H}} ] \frac{\sqrt{1 + Z \overline{T}} - 1}{\sqrt{1 + Z \overline{T}} + {T}_{C} / {T}_{H}} \\ where & ( 15 ) \\ \overline{T} = \frac{{T}_{H} + {T}_{C}}{2} & ( 16 ) \\ Z = \frac{{( {α}_{n} - {α}_{p} )}^{2}}{{[ \sqrt{{( ρκ )}_{n}} + \sqrt{{( ρκ )}_{p}} ]}^{2}} & ( 17 ) \\ \frac{{F}_{n}}{{F}_{p}} = \sqrt{\frac{{κ}_{p} {ρ}_{n}}{{κ}_{n} {ρ}_{p}}} & ( 18 )\end{matrix}$$

The first factor in the expression for the maximum efficiency (eq. 9) is the thermodynamic efficiency of a reversible Carnot cycle. The second factor represents the decrease in this efficiency resulting from the irreversible heat conduction along the branches and power dissipation in the form of Joule heat. For maximum efficiency, the factor ZT should be maximized, i.e., a high value of Z should be obtained over the widest possible range and at the highest operating temperature.

In practice, the two thermoelectric elements have nearly similar material constant. In this case, the concept of the Figure of merit for a single component is given by

$$Z = \frac{{α}^{2}}{ρκ} \qquad ( 19 )$$

This relationship is useful for comparing the relative thermoelectric efficiencies of various materials. The current state of the art is characterized by materials having figures of merit up to 3.5×10⁻³K⁻¹. It should be emphasized that, in actual device applications, there are other heat losses in the system and the efficiency given in equation 4 can never be fully realized.

### Refrigeration

In FIG. 2, a current I is passed through a pair of p & n elements with one of its junctions in thermal contact with a heat source and the other in contact with a heat sink. Under these conditions, the device pumps heat from the heat source to the heat sink, and under steady-state conditions the temperatures are T_{C} and T_{H} respectively. The parameters of principal importance in evaluating the performance of a refrigerator are the coefficient of performance (COP), the heat-pumping rate, and the maximum temperature difference that the device produces. The coefficient of performance (COP) is

$$COP = \frac{cooling obtained ( {Q}_{c} )}{power input ( {E}_{b} I )} \qquad ( 20 )$$

At the cold junction T_{C}, the Peltier heat removed is opposed by the thermal conduction of heat along the thermoelectric elements from the heat sink at temperature T_{H} and one half of the Joule heat produced in the thermoelectric circuit. The cooling obtained is given by
Q_{C}=αₙₚIT−κₜ(T_{H}−T_{C})−½²Rₜ (21)
Net heat
Peltier heat
Joule heat
Heat conducted
absorbed
transferred
flowing to
from surroundings
at cold
from cold
cold junction
and hot junction
junction
junction

The power input to the thermocouple circuit consists of αₙₚI(T_{H}−T_{C}) to overcome the developed Seebeck voltage and I²Rₜ to overcome the resistance of the thermo electric element branches. The power input, therefore, is

$$\begin{matrix}{E}_{b} I = {α}_{np} I ( {T}_{H} - {T}_{C} ) + {I}^{2} {R}_{t} \\ and the ( COP ) is & ( 22 ) \\ COP = \frac{{α}_{np} {IT}_{C} - {κ}_{t} ( {T}_{H} - {T}_{C} ) - 1 \text{/} 2 {I}^{2} {R}_{t}}{{α}_{np} I ( {T}_{H} - {T}_{C} ) + {I}^{2} {R}_{t}} & ( 23 )\end{matrix}$$

Thus, for a given pair of thermoelectric materials and for a given hot- and cold-junction temperature, the COP is a function of the current I, the electrical resistance Rₜ, and the thermal conductance κₜ. However, Rₜ and κₜ are not independent, and the COP reaches a maximum value when the dimensions of the thermoelectric elements satisfy equation (9) and the current is optimized. The expression for the maximum COP is

$${COP}_{max} = [ \frac{{T}_{H}}{{T}_{C} - {T}_{H}} ] \frac{\sqrt{1 + Z \overline{T}} - {T}_{C} \text{/} {T}_{H}}{\sqrt{1 + Z \overline{T}} + 1} \qquad ( 24 )$$

where T̅ and Z are defined in equation (9). The maximum COP of a thermoelectric refrigerator is related to the Carnot efficiency and to a factor containing Z and T, just as the maximum efficiency of a thermoelectric generator is related to these factors. A graph of COPₘₐₓ vs (T_{H}−T_{C}) for various values of the Figure of merit Z is given in FIG. 24. This graph shows that the maximum difference in temperature occurs under adiabatic conditions when the COP is zero. This graph also shows that, as the Figure of merit increases, the ΔTₘₐₓ also increases and, at a constant ΔT, the COPₘₐₓ is greater for materials with higher Figures of merit. A higher COP implies that less power is needed to pump the same quantity of heat. Therefore, the highest performance refrigerator is achieved with thermoelectric materials having the highest Figure of merit.

### Thermoelectric Properties

The Seebeck coefficient, electrical conductivity, and thermal conductivity are properties of materials that can be related to the atomic structure of the materials. The thermoelectric properties of some metals and semiconductors at room temperature are given in Table 1. For a metal, the highest Figure of merit is 0.6×10⁻³K⁻¹, and for semiconductors, it is 2.3×10⁻³K⁻¹. The latter yields efficiencies at least three times greater than those of metals.

TABLE 1

| | Seebeck | Electrical | Thermal | |
|---|---|---|---|---|
| | coefficient, | conductivity | conductivity | FIGURE |
| Material | μV/° C. | S/cm | W/(cm · K) | of merit, K⁻¹ |
| Cu | 2.5 | 5.9 × 10⁵ | 3.96 | 9.3 × 10⁻⁷ |
| Ni | 18 | 1.5 × 10⁵ | 0.87 | 5.6 × 10⁻⁵ |
| Bi | 75 | 8.6 × 10⁸ | 0.08 | 6.0 × 10⁻⁴ |
| Ge | 200 | 1000 | 0.636 | 6.3 × 10⁻⁷ |
| Si | 200 | 500 | 1.133 | 1.8 × 10⁻⁵ |
| InSb | 200 | 2000 | 0.17 | 4.7 × 10⁻⁴ |
| InAs | 200 | 3000 | 0.315 | 3.8 × 10⁻⁴ |
| Bi₂Te₃ | 220 | 1000 | 0.02 | 2.3 × 10⁻³ |
| ZnSb | 170 | 556 | 0.03 | 5.8 × 10⁻⁴ |

### SUMMARY OF THE INVENTION

These principles are embodied in the device called The Solid State Direct Heat to Cooling Converter. The device does not require any external electrical power source and the undesired heat is removed through an integral part of the device, the adiabatic heat accumulator, which not only collects heat but it expels it externally. The Solid State Direct Heat to Cooling Converter includes three sections. One section converts heat to electricity, the second section absorbs heat from the other two sections and expels it outside the device and the third opposite section converts electricity to cooling. As a rule of thumb, the hotter the heated section, the colder the opposite section.

To further improve performance, and to overcome other limitations that will become apparent upon reading and understanding this specification, the present invention discloses new high performance geometries.

In one form, the invention relates to a thermoelectric heat to cooling converter including Seebeck and Peltier devices and the adiabatic plane having venting and cooling holes embedded in the thermoelectric materials. The absence of additional material provides for improved electrical current transfer from Seebeck to Peltier device.

In another form, the invention relates to an alternate method of cooling the adiabatic plane by incorporating numerous cooling pipes along the virtual plane. The pipes may be used to cool the adiabatic plane by moving fluids, gasses or both.

In still another form, the invention relates to an alternate method of maximizing the power transfer from the Seebeck to Peltier device by adjusting the effective area of Seebeck and Peltier devices. This can be accomplished by dicing the devices into numerous posts defined by slots.

In still another form, the invention relates to an alternate method of adjusting the effective contact area of Peltier and/or Seebeck devices.

In still another form, the dicing of the thermoelectric elements may be accomplished after soldering the entire thermoelectric wafer to the subsystem and after assembling the components of the heat to cooling converter.

In still another form, the invention relates to an alternate method of adjusting the length to area 1/A ratio of thermoelectric pellets to maximize the device operating efficiency. By using an array of pellets instead of solid material, removal of the parasitic Joule heat is more efficient and as a result the operating efficiency of the heat to cooling converter is improved.

In still another form, the invention relates to an alternate method of selecting thermoelectric materials. While Bismuth Telluride is efficient, its maximum operating temperature is about 200 degree C. In applications, where higher temperatures are available, the material used in the power generating Seebeck device may be substituted by higher temperature materials such as Si—Ge compositions, Quantum Well structures, thermionic and other devices related to other tunneling phenomena.

In still another form, the invention relates to a method of selecting and connecting numerous p type and n type Seebeck elements to provide higher output voltages. Thus, smaller temperature difference across the Seebeck element provides higher voltages and related higher Seebeck power may be used to power up Peltier cells to obtain a greater thermal difference across the Peltier cells. The Seebeck device may be used to power up other appliances such as lamps, or other low voltage devices.

### BRIEF DESCRIPTION OF THE DRAWINGS

Other objects, advantages, features and characteristics of the present invention, as well as methods, operation and functions of related elements of the structure, and the combination of parts and economies of manufacture, will become apparent upon consideration of the following description and claims with reference to the accompanying drawings, all of which form a part of this specification, wherein like reference numerals designate corresponding parts in the various Figures.

FIG. 1 schematically depicts a conventional operable Seebeck device;

FIG. 2 schematically depicts a conventional operable Peltier cooling device;

FIG. 3 illustrates a perspective view of a thermoelectric cooling apparatus with cooling holes;

FIG. 4 illustrates a perspective view of a thermoelectric cooling apparatus with cooling pipes imbedded in p type and n type thermoelectric elements with the cooling substance flowing through the pipes;

FIG. 5 illustrates a perspective view of a thermoelectric cooling apparatus with the cooling substance flowing through adiabatic cooling channels;

FIGS. 6a, 6b, 6c & 6d illustrate a perspective view of a diced thermoelectric element formed from p and n type wafers;

FIGS. 7a & 7b illustrate an exploded perspective view of another converter of the present invention;

FIG. 8 illustrates a cross-sectional view of the thermal profile across the Peltier cell;

FIGS. 9, 10, 11 & 12 illustrate perspective views of a plane of constant temperature is realized in Peltier devices.

FIG. 13 illustrates a perspective view of a rectangular shaped heat to cooling converter;

FIG. 14 illustrates a perspective view of a cylinder shaped heat to cooling converter;

FIG. 15 illustrates a sectional view of a thermal profile of the heat to cooling converter;

FIG. 16 illustrates a perspective view of the geometry associated with the thermoelectric element used in computing the electrical and thermal conductivities which depend on the length to width (1/w) ratio of the thermoelectric element;

FIG. 17 illustrates a perspective view of the additional geometry with the 1/w ratio being much smaller resulting in lower the electro-thermal performance.

FIG. 18 illustrates a perspective view of the thermal profile of thermoelectric elements with high 1/w ratio;

FIG. 19 illustrates a perspective view of the thermal profile of thermoelectric elements with low 1/w ratio;

FIG. 20 illustrates an exploded perspective view of the heat to cooling converter with multiple Seebeck elements in order to obtain higher voltage outputs;

FIG. 21 illustrates an exploded perspective view of the assembly of multiple Seebeck cells.

FIG. 22 illustrates a perspective view of an assembled device;

FIG. 23 illustrates a perspective view of two thermoelectric elements of differing 1/w ratios;

FIGS. 24a and 24b illustrates a graph of Temperature differences.

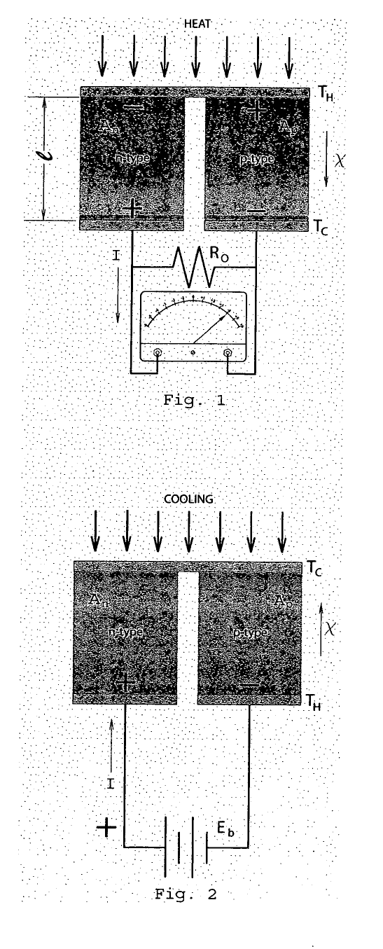

### DETAILED DESCRIPTION

In the following detailed description of the preferred embodiments, reference is made to the accompanying drawings which form a part hereof, and in which is shown by way of illustration specific preferred embodiments in which the invention may be practiced. It is to be understood that other embodiments may be utilized and that logical, mechanical and electrical changes may be made without departing from the spirit of scope of the invention. The following detailed description is, therefore, not to be taken in a limiting sense, and the scope of the present invention is defined only by the appended claims.

The conceptual ground work for the present invention involves using virtual planes of constant temperature intersecting the thermoelectric materials, methods of implementing effective and variable geometries and contact areas of thermoelectric materials, number of thermoelectric elements embodied in the conversion process, optimized 1/w ratios of thermoelectric elements and incorporating multitudes of thermoelectric materials in the structure of the heat to cooling converters. My previous application Ser. No. 10/992,026 filed on May 5, 2005 entitled ‘Heat to Cooling Converter’ is incorporated by reference in its entirety.

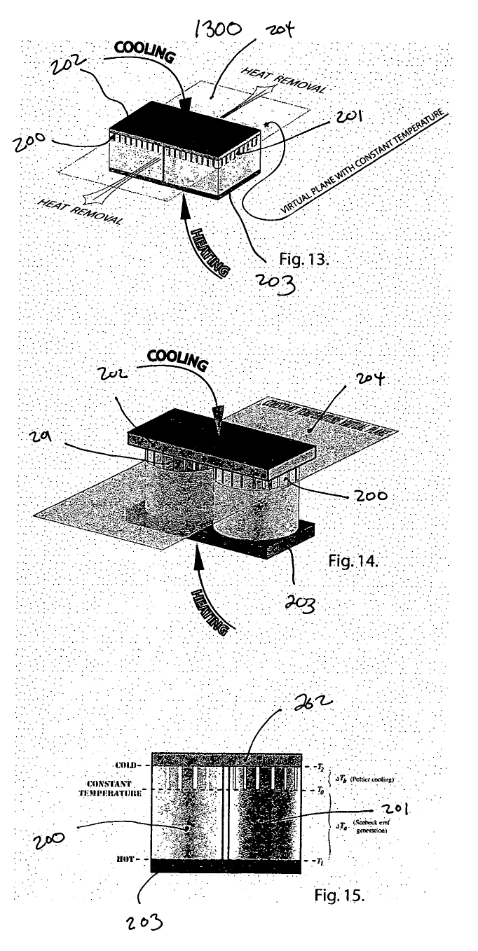

Referring now to FIGS. 13, 14 & 15, an illustration of the virtual adiabatic constant temperature planes are presented. Reference numerals used in FIG. 13 which are like, similar or identical to reference numerals used in FIGS. 14 & 15 indicate like, similar or identical components. A thermoelectric converter 1300 includes a first thermoelectric element 200 for example of p-type semiconductor material, the second thermoelectric element 201 of n-type semiconductor material, or the first thermoelectric element 200 and the effect second thermoelectric element 201 could be made from correspondingly behaving materials not necessarily semiconductor material. The converter 1300 may constructed either in whole or in part using thin film technology for weight reduction. The contact electrodes 202 and 203 which are positioned at opposite ends of the first thermoelectric element 200 and the second thermoelectric element 201 and the virtual plane 204 which passes through the sides of the first and second thermoelectric elements 200, 201 could be maintained at constant temperature. The present invention may employ a variety of thermoelectric materials and structures such as quantum wells or displacement current geometries, including but is not limited to Bismuth Telluride. The first thermoelectric element 200 and the second thermoelectric element 201 are shown as rectangles, but as the following description will show other shapes are within the scope of the present invention. The teaching of the present invention applies equally to all shapes of thermoelectric elements including rectangular and cylinders.

FIG. 14 shows the first thermoelectric element 200 and the second thermoelectric element 201 as cylinders. FIG. 15 shows the delta temperature due to Peltier cooling above the constant temperature virtual plane 204 and the delta temperature due to Seebeck emf generation below the constant temperature virtual plane 204.

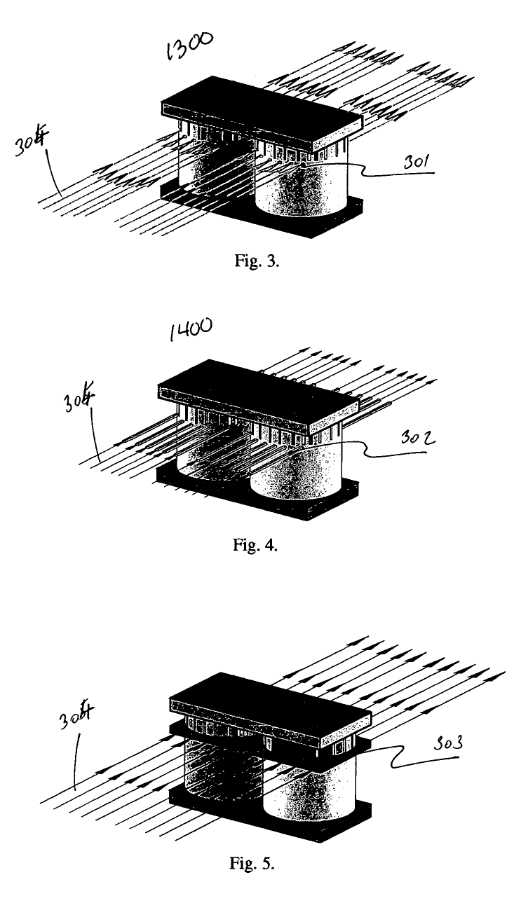

Referring now to FIGS. 3, 4 and 5, these figures show the cooling substance as arrows to establish the plane of constant temperature within the first and second thermoelectric elements 200 and 201.

FIG. 3 illustrates a thermoelectric cooling apparatus with cooling holes in p type and n type semiconductor elements with a cooling substance flowing through the holes provides cooling and defines the thermal equilibrium plane held at constant temperature. The thermoelectric cooling converter in FIG. 3 includes cooling ports 301 formed during the process of forming the thermoelectric elements 200 and 201. These cooling ports 301 provide for the cooling of thermoelectric elements 200 and 201 and the temperature of the virtual adiabatic plane 204 is maintained constant by the flow of cooling substance 304, such as fluid or air.

The converter 1400 in FIG. 4 has imbedded cooling pipes 302 in thermoelectric elements 200 and 201. The cooling substance 304 moving through these cooling pipes 302 establishes the adiabatic plane 204 of constant temperature intersecting both thermoelectric elements 200 and 201. In both the converter 1300 of FIG. 13 and the converter 1400 of FIG. 14, the openings in the thermoelectric elements 200 and 201 should not affect the current flow from the Seebeck to Peltier device.

FIG. 5 illustrates a thermoelectric cooling apparatus with the cooling substance flowing through the adiabatic cooling channels 303 to provide cooling for the thermoelectric elements and to electrically connect the Seebeck and Peltier devices;

In FIG. 5, the virtual adiabatic plane 204 of constant temperature is formed by positioning electrically highly conductive channels 303 between the thermoelectric elements 200 and 201. These thermoelectric elements 200 and 201 are cooled by the flow of the cooling substance 304 along the conductive channel 303.

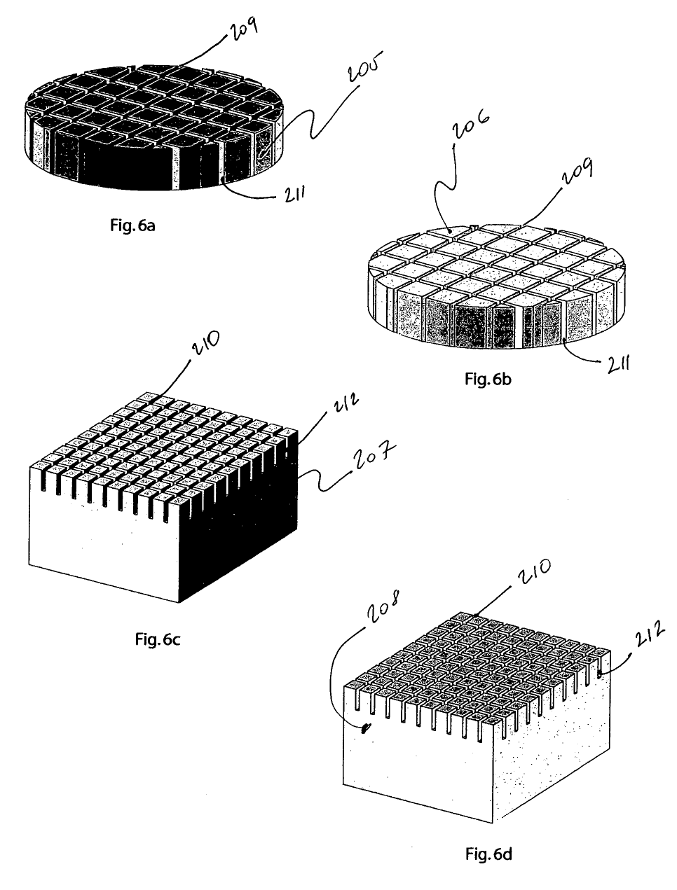

Referring now to FIGS. 6a, 6b, 6c & 6d, different geometries of thermoelectric elements are illustrated. FIGS. 6a, 6b, 6c & 6d depict a diced thermoelectric p and n type semiconductor wafers in order to improve efficiency and to adjust effective contact area to substantially maximize power transfer from Seebeck to Peltier device. The thermoelectric elements 205 & 206 are cylindrical shaped having a circular cross section and may be pellets, and the thermoelectric elements 205 and 206 may be cut from the crystal ingot and diced, resulting in the structure shown in FIGS. 6a-6d to improve and nearly optimize the power transfer from the Seebeck device to the Peltier device. The width of slots 209 & 211 may be defined empirically to nearly maximize the Joule heat removal from the individual thermoelectric elements. The thermoelectric elements 207 & 208 are rectangular and as such not necessarily drawn from crystal ingots but could be formed by sintering or other non crystal growing techniques. The upper portion of these thermoelectric elements is slotted with slots 210 & 207 to substantially optimize power transfer from the Seebeck section.

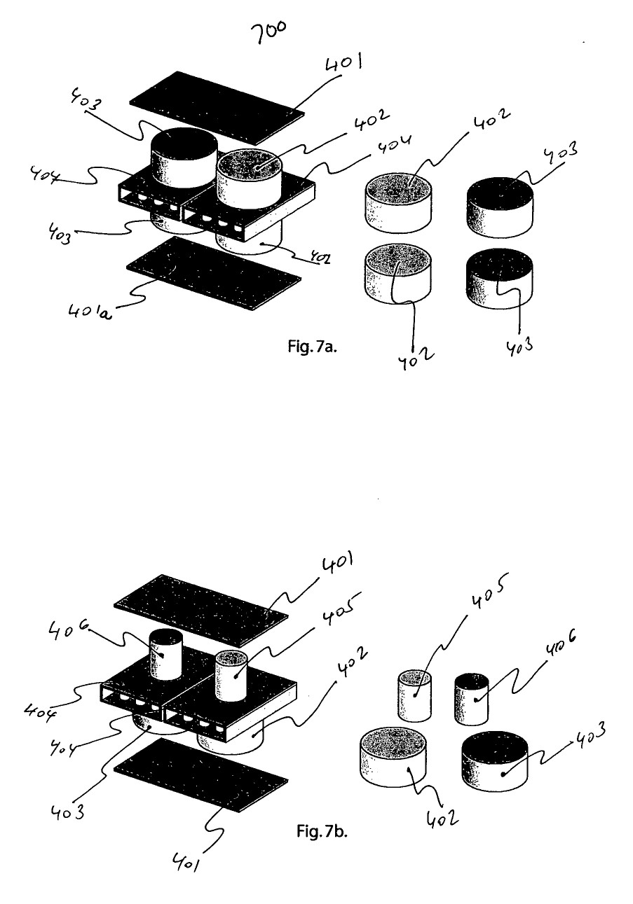

FIGS. 7a & 7b illustrate components used in the assembly and illustrate different shapes of thermoelectric elements. The converter of FIGS. 7a and 7b adjusts the effective contact areas of thermoelectric elements in order to improve the power transfer from Seebeck to Peltier device and to improve the overall efficiency by enhancing the removal of parasitic Joules heat from the thermoelectric elements. In FIG. 7a, the converter 700 includes a first portion of the two thermoelectric elements 402 & 403 to form the Seebeck power generating cell and a second portion of the two near identical thermoelectric elements 402 & 403 to form the Peltier cell. The contact electrode 401 is used to connect electrically the first portion of the two thermoelectric elements 402 and 403 and the second near identical contact electrode 401a is used to connect the second portion of the two thermoelectric elements 402 and 403, forming the two Peltier cells. The opposite ends of the Seebeck and Peltier cells are electrically connected through the adiabatic conductors 404. The converter 700 is symmetrical in that either side can be use as either Peltier cooling device or the electricity generating Seebeck device. FIG. 7b illustrates a similar heat to cooling converter; however, the Peltier thermoelectric elements 405 & 406 have a smaller cross-sectional contact area and facilitate improved power transfer efficiency. This converter is producing lower temperatures.

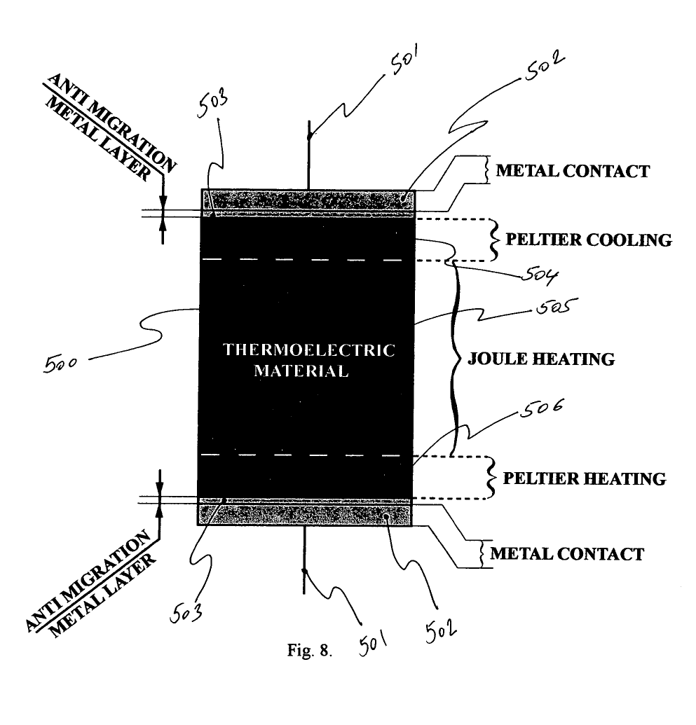

FIG. 8 presents a thermal and construction profile of the Peltier cell. The thermoelectric material 500 of the thermoelectric element may be semiconductor, metal or other suitable media. The electrical conductors 501 on each end of the thermoelectric element supply emf to the device. Between the electrical conductors 501 and the Peltier cell 500 are two conductive metal layers 503. The function of layers 503 is to prevent metal migration of contact electrode 502 into the Peltier thermoelectric material which would adversely affect the performance. The figure also illustrates the thermal profile of the device which is powered up. One end 504 exhibits cooling effect; the middle section 500 exhibits heating due to the Joule heat, and the opposite end 506 is heated due to the Peltier heat. The thermal profile across the Peltier cell with Peltier heat and the Joule heat adds algebraically while the Peltier cooling subtracts from the sum of the sum. The thickness of layers 503 usually is in the range of 5-10 μm and is made of metals having a larger work function with metals such as Nickel have proven to be very effective. Metal contact electrodes 502 are used to provide easy soldering ability and may be approximately 5-10 μm thick, and Sn is effective.

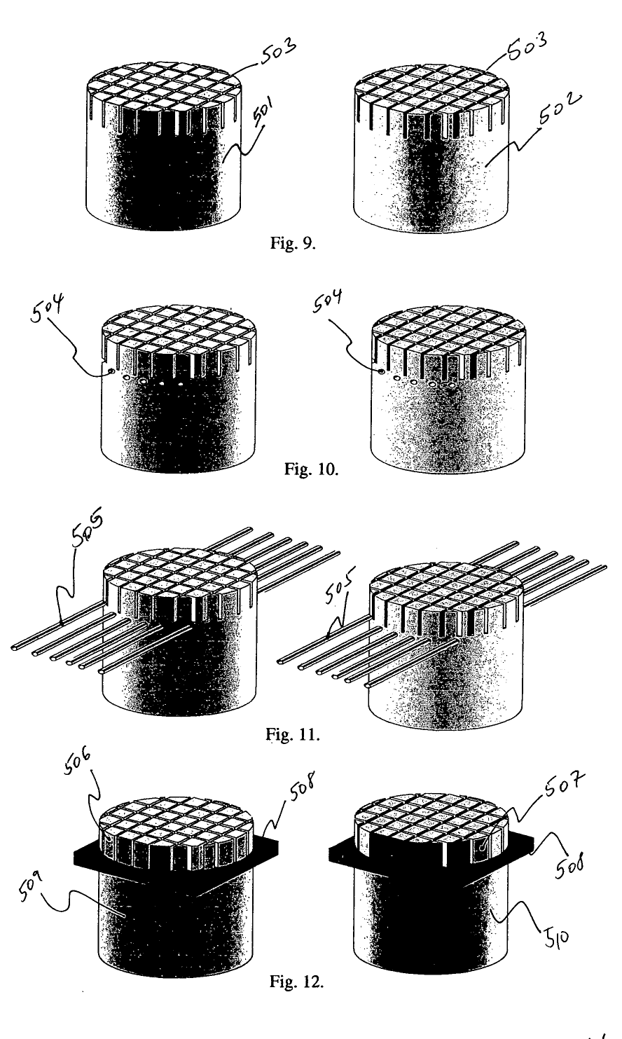

FIG. 9 illustrates two single blocks of thermoelectric elements 501 & 502. The slots 503 on top of element 501 are used to maximize the cooling efficiency. FIG. 10 shows cooling ports 504 which provide the virtual constant temperature plane by cooling the thermoelectric elements. These holes may be manufactured by drilling the thermoelectric elements or by alternate suitable manufacturing pressing techniques. FIG. 11 illustrates cooling tubes 505 which are imbedded in the thermoelectric elements and which may be made of electrical conductive materical. The cooling substance flows through the cooling tubes 505 to provide cooling and to define the virtual adiabatic plane of constant temperature. FIG. 12 shows Peltier elements 506 & 507 of opposite thermoelectric types, adiabatic planes 508 which provide constant temperature on one end of four thermoelectric elements 506, 507, 509 & 510. The cooling substance flows through the channel 508 to provide thermal insulation and isolation between elements 506 & 509 and 507 & 510 while providing low ohmic electrical connection between thermoelectric elements 506 & 509 and 507 & 510.

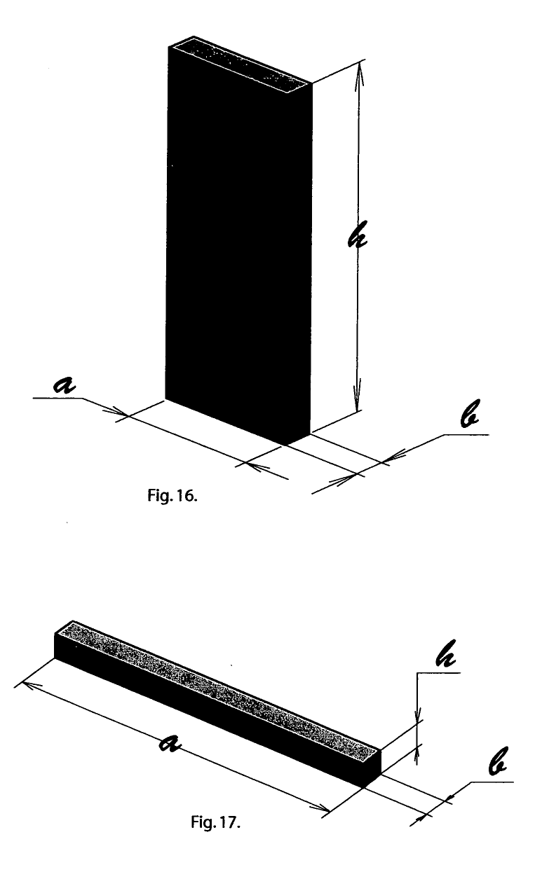

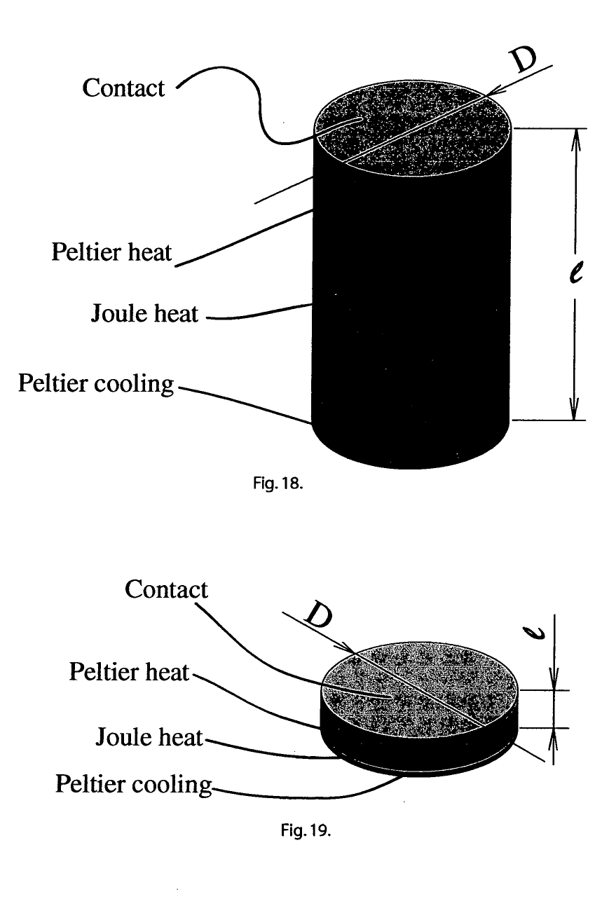

Referring now to FIGS. 16 & 17, the FIGS. 16 and 17 show two thermoelectric elements which are rectangular and with 1/w ratios that vary greatly. In FIG. 16, a relatively large 1/w ratio provides large surface area to expel unwanted Joule heat by conduction and radiation. In contrast, FIG. 17 illustrates an element with a relatively smaller 1/w ratio thus expelling unwanted Joules heat with less efficiency, and the element should function with lower efficiency. A similar effect should be expected with the cylindrical thermoelectric element as is presented in FIGS. 18 & 19.

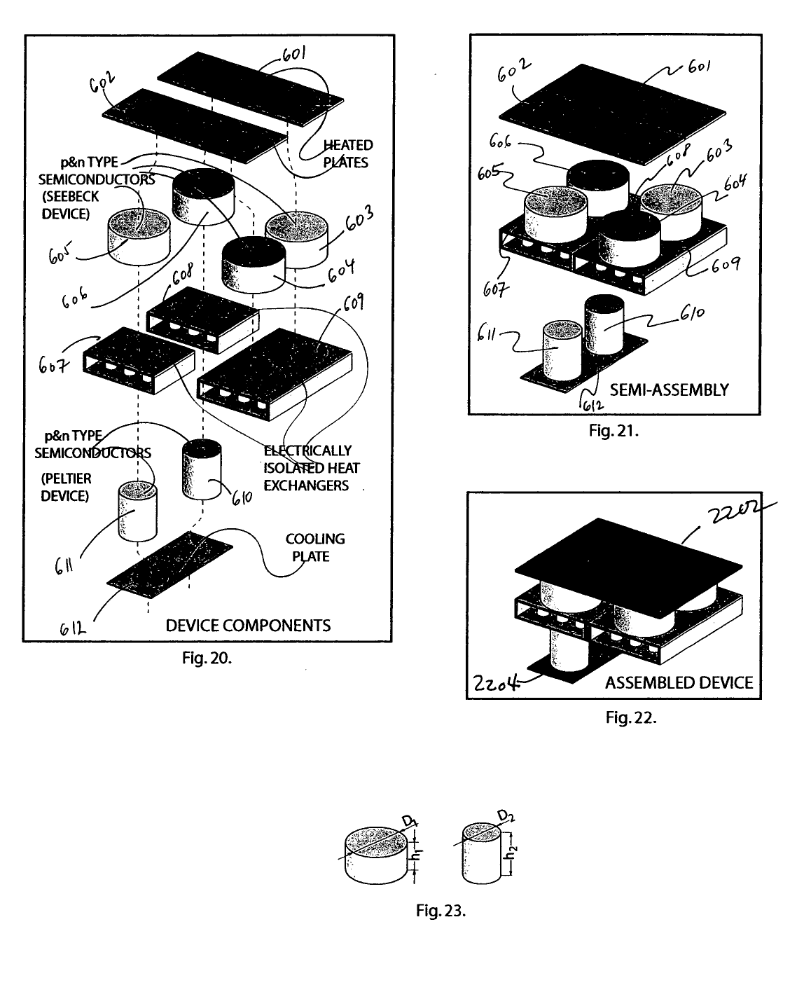

Another thermoelectric heat to cooling converter in FIG. 20 is illustrated with improved performance. With multiple cells connected electrically in series, a smaller ΔT across the Seebeck cell is required, or lower Peltier cell temperatures are obtained.

Instead of a pair of thermoelectric elements that form a Seebeck device, a number greater than two thermoelectric elements are connected in series, thus increasing the voltage output from the emf Seebeck generator. In FIG. 20 two pairs or four thermoelectric elements 603, 604, 605 & 606 are used, thus the voltage output per degree C. is being doubled as contrasted with the case of a single pair of thermoelectric elements. Three adiabatic heat exchangers 607, 608 & 609 are used to maintain the temperature of all six thermoelectric elements 603, 604, 605, 606, 610 & 611. To increase the temperature difference across the Peltier thermoelectric elements 610 & 611, the effective contact area of the cell is reduced with respect to the thermoelectric elements 603, 604, 605, and 606, while the 1/w ratio is maintained substantially at near optimum. A semi-assembled heat to cooling converter is presented in FIG. 21, and a assembled converter is viewed in FIG. 22, with upper, dual side representing the Seebeck emf generator and the bottom, smaller diameter device provides cooling; the red Seebeck plate 2202 representing the heated region and the blue plate 2204 representing the Peltier cooling side.

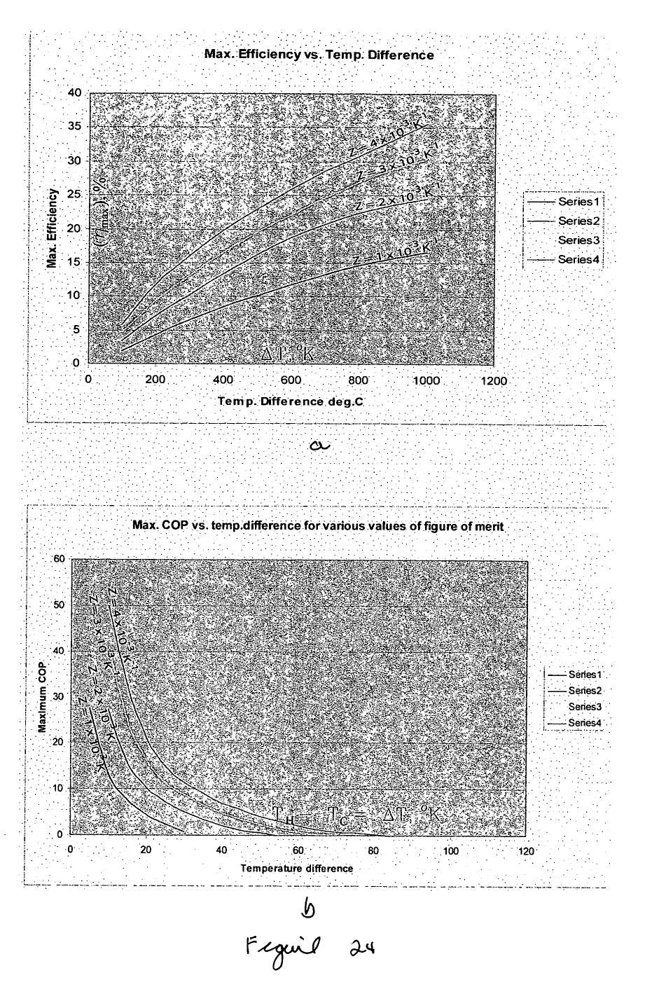

In FIG. 23, two thermoelectric elements are shown of different 1/w ratios.

It will be understood by those skilled in the art that the embodiments set forth hereinbefore are merely exemplary of the numerous arrangements for which the invention may be practiced, and as such may be replaced by equivalents without departing from the invention which will now be defined by appended claims.

Although an embodiment of the present invention has been shown and described in detail herein, along with certain variants thereof, many other varied embodiments that incorporate the teachings of the invention may be easily constructed by those skilled in the art. Accordingly, the present invention is not intended to be limited to the specific form set forth herein, but on the contrary, it is intended to cover such alternatives, modifications, and equivalents, as can be reasonably included within the spirit and scope of the invention.

1) A heat to cooling converter, comprising:
a first type of thermoelectric element coupled to an adiabatic plane;
said adiabatic plane absorbing heat from said first type of thermoelectric element;
a second type of thermoelectric element coupled to said adiabatic plane;
wherein said first type of thermoelectric element includes a port for accepting a cooling substance.

2) A heat to cooling converter as in claim 1, wherein said first type of the thermoelectric element includes a Seebeck element.

3) A heat to cooling converter as in claim 1 wherein said second type of thermoelectric element includes a Peltier device.

4) A heat to cooling converter as in claim 1, wherein said port includes a tube to accept a cooling substance.

5) A heat to cooling converter as in claim 4, wherein said tube includes electrical conductive material.

6) A heat to cooling converter as in claim 4 wherein said tube is positioned approximately in said adiabatic plane.

7) A heat to cooling converter, comprising:
a first type of thermoelectric element coupled to an adiabatic plane;
said adiabatic plane absorbing heat from said first type of thermoelectric element;
a second type of thermoelectric element coupled to said adiabatic plane;
wherein said first type of thermoelectric element includes a slot for accepting a cooling substance.

8) A heat to cooling converter as in claim 7, wherein said first type of the thermoelectric element includes a Seebeck element.

9) A heat to cooling converter as in claim 7 wherein said second type of thermoelectric element includes a Peltier device.

10) A heat to cooling converter, comprising:
a first type of thermoelectric element coupled to an adiabatic plane;
said adiabatic plane absorbing heat from said first type of thermoelectric element;
a second type of thermoelectric element coupled to said adiabatic plane;
wherein said first type of thermoelectric element includes a portion having a different length to area (1/a) ratio then a portion of said second type of thermoelectric element.

11) A heat to cooling converter as in claim 10 wherein said first type of the thermoelectric element includes a Seebeck element.

12) A heat to cooling converter as in claim 10 wherein said second type of thermoelectric element includes a Peltier device.

13) The heat to cooling converter as in claim 2, wherein the Seebeck device includes a pellet for higher output voltage.

14) The heat to cooling converter as in claim 11, wherein said pellet is diced into smaller pellets to provide higher power transfer for improved performance.

15) The heat to cooling converter as in claim 3, wherein the Peltier device includes a power converting element have smaller contact area for improved conversion.
